(19) United States
(12) Patent Application Publication
(10) Pub. No.: US 2020/0243485 A1
(43) Pub. Date: Jul. 30, 2020

(54) Semiconductor device package having integrated circuits with I/O interface circuits powered by the same core voltage

(71) Applicant: Sunplus Technology Co., Ltd., Hsinchu (TW)

(72) Inventors: Ming-Chang Su, Hsinchu County (TW); Hwan-Rei Lee, Hsinchu City (TW); Hao-Chang Chang, Taipei City (TW)

(21) Appl. No.: 16/262,869

(22) Filed: Jan. 30, 2019

(51) Int. Cl. H01L 25/065; H03K 19/0175

(52) U.S. Cl. CPC H01L 25/0657; H03K 19/017509; H01L 2225/06568; H01L 2225/0651; H01L 2225/06506

(57) ABSTRACT

A semiconductor device package has two integrated circuits. Each of the two integrated circuits has a core circuit and a digital input/output (I/O) interface circuit. The core circuits of the two integrated circuits are powered by two different core voltages, and the I/O circuits of the two integrated circuits are powered by the same core voltage selected from the two different core voltages.

### BACKGROUND OF THE INVENTION

### 1. Field of the Invention

The present invention relates to a semiconductor device package, and more particularly, to a semiconductor device package having integrated circuits with I/O interface circuits powered by the same core voltage.

### 2. Description of the Prior Art

In order to meet the specification and application of a printed circuit board (PCB), the power supply voltage of the digital input/output (I/O) interfaces of chips on the PCB is usually 1.8 volts, 3.3 volts or 5 volts. However, the I/O power supply voltage of 1.8 volts, 3.3 volts or 5 volts is usually too high for chip-to-chip applications in a system-in-package (SIP) device. Accordingly, it can easily cause problems such as a low transmission speed, high power consumption, and a large layout area of the SIP device.

### SUMMARY OF THE INVENTION

An embodiment of the present invention discloses a semiconductor device package having a first integrated circuit and a second integrated circuit. The first integrated circuit is formed in a first substrate and comprises a first core circuit and a first digital input/output (I/O) interface circuit. The first core circuit is coupled to a first power supply terminal and powered by a first core voltage. The first power supply terminal provides the first core voltage. The first digital I/O interface circuit is coupled to the first power supply terminal and powered by the first core voltage. The second integrated circuit is formed in a second substrate and coupled to the first integrated circuit. The second integrated circuit comprises a second core circuit and a second digital I/O interface circuit. The second core circuit is powered by a second core voltage. A voltage level of the second core voltage is different from a voltage level of the first core voltage. The second digital I/O interface circuit is coupled to the first digital I/O interface circuit and the first power supply terminal. The second digital I/O interface circuit is powered by the first core voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a semiconductor device package according to a first embodiment of the present invention.

FIG. 2 shows the electrical connections of components of the semiconductor device package in FIG. 1.

FIG. 3 shows the electrical connections of components of another semiconductor device package according to a second embodiment of the present invention.

FIG. 4 shows the electrical connections of components of another semiconductor device package according to a third embodiment of the present invention.

FIG. 5 shows the electrical connections of components of another semiconductor device package according to a fourth embodiment of the present invention.

### DETAILED DESCRIPTION

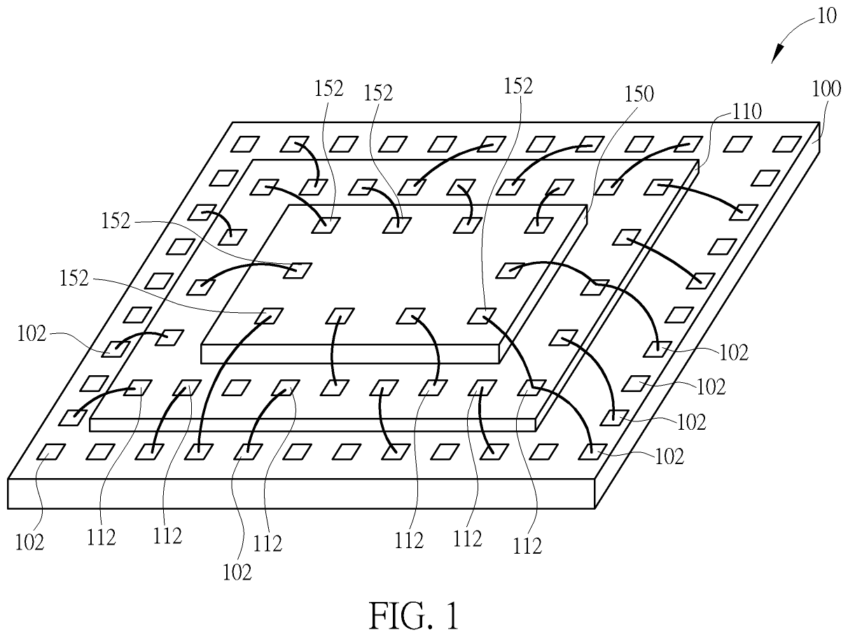

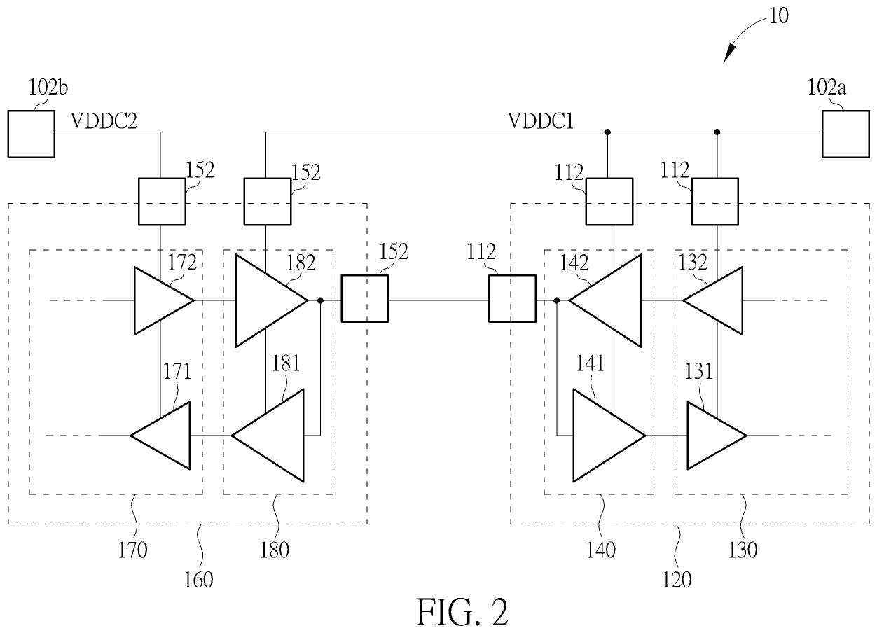

Please refer to FIGS. 1 and 2. FIG. 1 is a schematic diagram of a semiconductor device package 10 according to a first embodiment of the present invention, and FIG. 2 shows the electrical connections of components of the semiconductor device package 10 in FIG. 1. The semiconductor device package 10 is a system-in-package (SIP) device and comprises two substrates 110 and 150. The substrate 150 is stacked on the substrate 110, and the substrate 110 may be embedded on a base board 100. The base board 100 may be a printed circuit board (PCB) and has a plurality of pads 102. The substrate 110 has a plurality of pads 112, and the substrate 150 has a plurality of pads 152. In the embodiment, the pads 102, 102 and 152 are coupled through wire bonding. However, the present invention is not limited thereto. For example, the base board 100 and the two substrates 110 and 150 may be coupled by using at least a ball grid array (BGA), and the semiconductor device package 10 is a package-on-package (POP) device. In another embodiment, the substrate 150 may be directly stacked on the base board 100. In other words, the substrate 150 and the substrate 110 may both be stacked on the base board 100 directly. For example, each of the two substrates 110 and 150 may be packaged in a quad flat package (QFP), which is directly embedded on the base board 100 via leads of a lead frame.

In addition, an integrated circuit 120 of the semiconductor device package 10 is formed in the substrate 110, and an integrated circuit 160 of the semiconductor device package 10 is formed in the substrate 150. As shown in FIG. 2, a pad 102a selected from the pads 102 is used as a power supply terminal to provide a core voltage VDDC1, and another pad 102b selected from the pads 102 is used as another power supply terminal to provide another core voltage VDDC2. A voltage level of the core voltage VDDC1 is different from a voltage level of the core voltage VDDC2. For example, the voltage level of the core voltage VDDC1 may be 1.2 volts, and the voltage level of the core voltage VDDC2 may be 0.8 volts. However, the present invention is not limited thereto.

The integrated circuit 120 comprises a core circuit 130 and a digital input/output (I/O) interface circuit 140. The core circuit 130 and the digital I/O interface circuit 140 are coupled to the power supply terminal 102a and powered by the core voltage VDDC1. The integrated circuit 160 is coupled to the integrated circuit 120 and comprises a core circuit 170 and a digital I/O interface circuit 180. The two core circuits 130 and 170 communicate with each other via the digital I/O interface circuits 140 and 180. The core circuit 170 is coupled to the power supply terminal 102b and powered by the core voltage VDDC2. The digital I/O interface circuit 180 is coupled to the digital I/O interface circuit 140 via the pads 152 and 112 and coupled to the power supply terminal 102a via one of the pads 152. Accordingly, the digital I/O interface circuit 180 of the integrated circuit 160 could be completely powered by the core voltage VDDC1. Since the core circuit 130, the digital I/O interface circuit 140 and the digital I/O interface circuit 180 are powered by the core voltage VDDC1, it is unnecessary to provide any I/O voltage different from the core voltage VDDC1 to the two digital I/O interface circuits 140 and 180. Therefore, the semiconductor device package 10 may have a high transmission speed between the two digital I/O interface circuits 140 and 180, low power consumption, and a small layout area.

In an embodiment of the present invention, the core circuit 130 may have an input buffer 131 and an output buffer 132, and the digital I/O interface circuit 140 may have an I/O input buffer 141 and an I/O output buffer 142. The input buffer 131 receives signals from the digital I/O interface circuit 140, and the output buffer 132 outputs signals to the digital I/O interface circuit 140. The I/O input buffer 141 receives signals from the digital I/O interface circuit 180 via the pads 152 and 112, and the I/O output buffer 142 outputs signals to the digital I/O interface circuit 180 via the pads 112 and 152. Similarly, the core circuit 170 of the integrated circuit 160 may have an input buffer 171 and an output buffer 172, and the digital I/O interface circuit 180 may have an I/O input buffer 181 and an I/O output buffer 182. The input buffer 171 receives signals from the digital I/O interface circuit 180, and the output buffer 172 outputs signals to the digital I/O interface circuit 180. The I/O input buffer 181 receives signals from the digital I/O interface circuit 140 via the pads 112 and 152, and the I/O output buffer 182 outputs signals to the digital I/O interface circuit 140 via the pads 152 and 112.

In an embodiment of the present invention, the voltage level of the core voltage VDDC1 is greater than the voltage level of the core voltage VDDC2, and the I/O input buffer 181 and the I/O output buffer 182 may be thick-oxide devices capable of bearing the core voltage VDDC1 higher than the core voltage VDDC2. The voltage level of the core voltage VDDC1 may be 1.2 volts, and the voltage level of the core voltage VDDC2 may be 0.8 volts.

In an embodiment of the present invention, the voltage level of the core voltage VDDC1 is greater than the voltage level of the core voltage VDDC2, and the I/O input buffer 181 and the I/O output buffer 182 may be thin-oxide devices having a specific circuit for bearing the core voltage VDDC1 higher than the core voltage VDDC2.

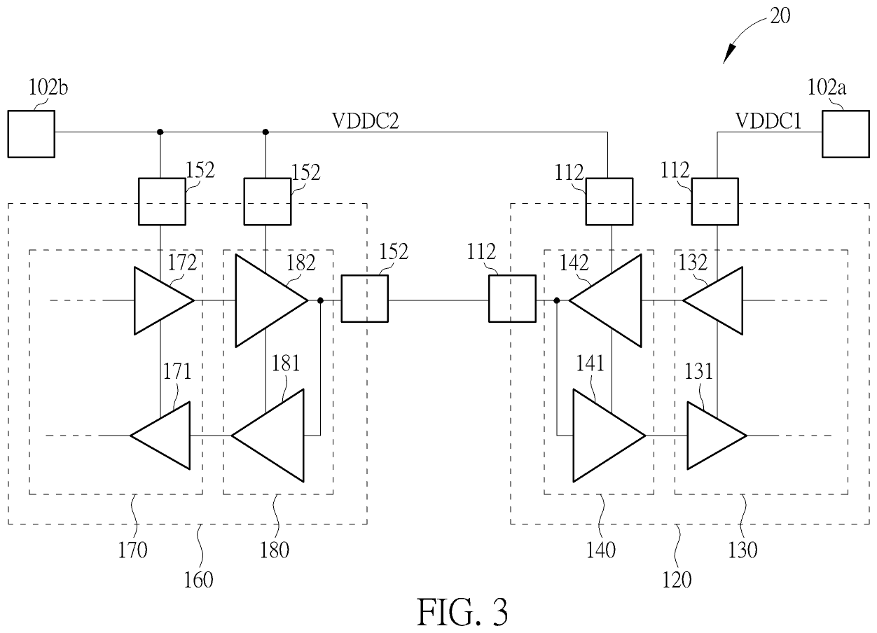

Please refer to FIG. 3. FIG. 3 shows the electrical connections of components of another semiconductor device package 20 according to a second embodiment of the present invention. The semiconductor device package 20 is similar to the semiconductor device package 10 shown in FIG. 2. The main difference between the semiconductor device packages 20 and 10 is that in the semiconductor device package 20, the digital I/O interface circuit 140, the core circuit 170 and the digital I/O interface circuit 180 are powered by the core voltage VDDC2 while the core circuit 130 is powered by the core voltage VDDC1. In the embodiment, the voltage level of the core voltage VDDC2 may be less than the voltage level of the core voltage VDDC1.

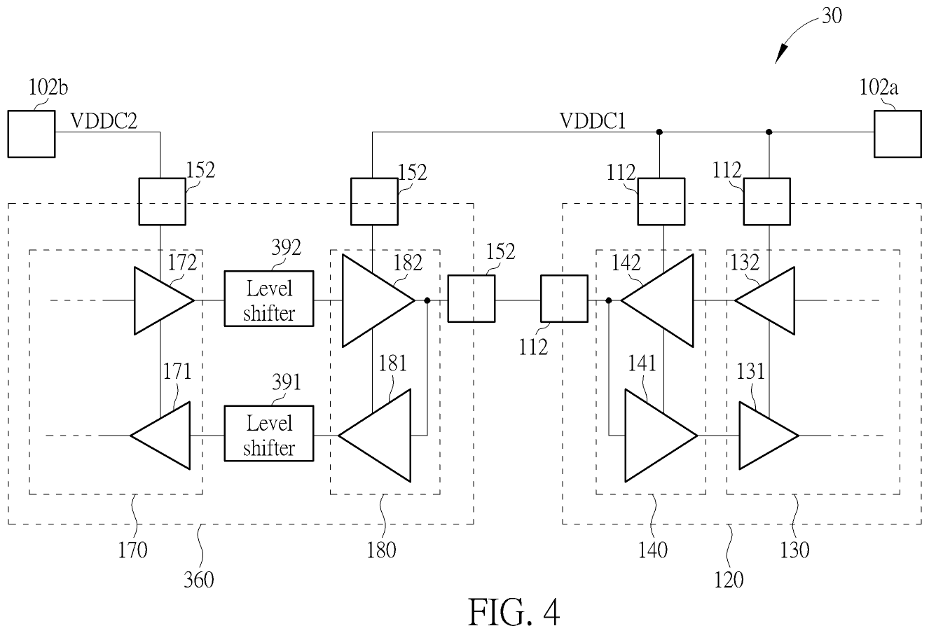

Please refer to FIG. 4. FIG. 4 shows the electrical connections of components of another semiconductor device package 30 according to a third embodiment of the present invention. The semiconductor device package 30 is similar to the semiconductor device package 10 shown in FIG. 2. The main difference between the semiconductor device packages 30 and 10 is that the integrated circuit 160 of the semiconductor device package 10 is replaced by an integrated circuit 360 of the semiconductor device package 30. The integrated circuit 360 comprises two level shifters 391 and 392, the core circuit 170 and the digital I/O interface circuit 180. The level shifter 391 is coupled between the input buffer 171 and the I/O input buffer 181 to shift a peak voltage of the output signals of the I/O input buffer 181 from the core voltage VDDC1 to the core voltage VDDC2. The level shifter 392 is coupled between the output buffer 172 and the I/O output buffer 182 to shift a peak voltage of the output signals of the output buffer 172 from the core voltage VDDC2 to the core voltage VDDC1.

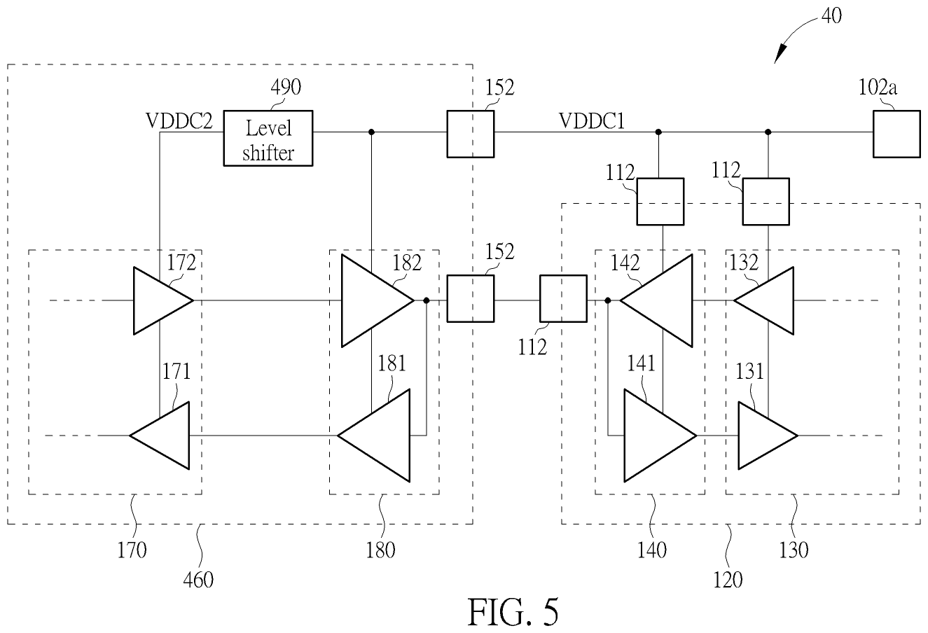

Please refer to FIG. 5. FIG. 5 shows the electrical connections of components of another semiconductor device package 40 according to a fourth embodiment of the present invention. The semiconductor device package 40 is similar to the semiconductor device package 10 shown in FIG. 2. The main difference between the semiconductor device packages 40 and 10 is that the integrated circuit 160 of the semiconductor device package 10 is replaced by an integrated circuit 460 of the semiconductor device package 40. The integrated circuit 460 comprises a level shifter 490, the core circuit 170 and the digital I/O interface circuit 180. The level shifter 490 is coupled to the power supply terminal 102a and the core circuit 170 to convert the core voltage VDDC1 to the core voltage VDDC2. Accordingly, power consumed by the core circuit 170 could be provided by the power supply terminal 102a. In other words, the integrated circuits 120 and 460 could be completely powered by the core voltage VDDC1, and all power consumed by the integrated circuits 120 and 460 is provided by the power supply terminal 102a.

In summary, since two the digital I/O interface circuits of different integrated circuits could be powered by the same core voltage, it is unnecessary to provide any I/O voltage different from the core voltage to the two digital I/O interface circuits. Therefore, the semiconductor device package may have a high transmission speed between the two digital I/O interface circuits, low power consumption, and a small layout area.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device package comprising:
a first integrated circuit formed in a first substrate and comprising:
a first core circuit coupled to a first power supply terminal and powered by a first core voltage, wherein the first power supply terminal provides the first core voltage; and
a first digital input/output (I/O) interface circuit coupled to the first power supply terminal and powered by the first core voltage; and
a second integrated circuit formed in a second substrate coupled to the first integrated circuit, and comprising:
a second core circuit powered by a second core voltage, wherein a voltage level of the second core voltage is different from a voltage level of the first core voltage; and
a second digital I/O interface circuit coupled to the first digital I/O interface circuit and the first power supply terminal, and powered by the first core voltage.

2. The semiconductor device package of claim 1, wherein the voltage level of the first core voltage is greater than the voltage level of the second core voltage, and the second digital I/O interface circuit comprises at least a thick-oxide device for receiving the first core voltage from the first power supply terminal.

3. The semiconductor device package of claim 1, wherein the second digital I/O interface circuit comprises:
an I/O input buffer for receiving signals from the first digital I/O interface circuit; and
an I/O output buffer for outputting signals to the first digital I/O interface circuit; and
wherein the second core circuit comprises:
an input buffer, for receiving signals from the I/O input buffer; and
an output buffer, for outputting signals to the I/O output buffer.

4. The semiconductor device package of claim 3, wherein the voltage level of the first core voltage is greater than the voltage level of the second core voltage, the second integrated circuit further comprises a first level shifter and a second level shifter, the first level shifter is coupled between the I/O input buffer and the input buffer for shifting a peak voltage of output signals of the I/O input buffer from the first core voltage to the second core voltage, and the second level shifter is coupled between the output buffer and the I/O output buffer for shifting a peak voltage of output signals of the output buffer from the second core voltage to the first core voltage.

5. The semiconductor device package of claim 1, wherein the voltage level of the first core voltage is less than the voltage level of the second core voltage.

6. The semiconductor device package of claim 1, wherein the first core circuit and the second core circuit communicate with each other via the first digital I/O interface circuit and the second digital I/O interface circuit.

7. The semiconductor device package of claim 1, wherein the second core circuit is coupled to a second power supply terminal to receive the second core voltage from the second power supply terminal.

8. The semiconductor device package of claim 1, wherein power consumed by the second core circuit is provided by the first power supply terminal.

9. The semiconductor device package of claim 8, wherein the second integrated circuit further comprises a level shifter coupled between the first power supply terminal and the second core circuit and configured to convert the first core voltage to the second core voltage.

10. The semiconductor device package of claim 1, wherein the second substrate is stacked on the first substrate.
